(19) United States
(12) Patent Application Publication
(10) Pub. No.: US 2026/0156859 A1
(43) Pub. Date: Jun. 4, 2026

(54) SEMICONDUCTOR DEVICE

(71) Applicant: Nippon Telegraph and Telephone Corporation, Tokyo (JP)

(72) Inventors: Takuya Tsutsumi, Tokyo (JP); Hideaki Matsuzaki, Tokyo (JP); Hiroki Sugiyama, Tokyo (JP)

(73) Assignee: Nippon Telegraph and Telephone Corporation, Tokyo (JP)

(21) Appl. No.: 18/685,828

(22) PCT Filed: Oct. 6, 2021
(86) PCT No.: PCT/JP2021/036944

§ 371 Date: Feb. 22, 2024

(51) Int. Cl. H10D 30/47; H10D 30/01; H10D 64/23; H10D 64/27; H10D 84/01; H10D 84/83

(52) U.S. Cl. CPC H10D 30/4755; H10D 30/015; H10D 64/2565; H10D 64/518; H10D 84/0149; H10D 84/83125; H10D 30/474

(57) ABSTRACT

An embodiment semiconductor device is a field-effect transistor that includes a first barrier layer including a compound semiconductor, a channel layer including a compound semiconductor that is formed on the first barrier layer, a second barrier layer including a compound semiconductor that is formed on the channel layer, a gate electrode formed on the second barrier layer, and a source electrode and a drain electrode formed with the gate electrode interposed therebetween, and the field-effect transistor includes a first carrier supply layer formed on the first barrier layer side of the channel layer and a second carrier supply layer formed between the gate electrode and the channel layer and further includes a groove in a region where the gate electrode is formed, in which the source electrode and the drain electrode are formed on the first barrier layer side of the channel layer.

### CROSS-REFERENCE TO RELATED APPLICATIONS

This application is a national phase entry of PCT Application No. PCT/JP2021/036944, filed on Oct. 6, 2021, which application is hereby incorporated herein by reference.

### TECHNICAL FIELD

The present invention relates to a semiconductor device.

### BACKGROUND

Electronic devices and integrated circuits, capable of handling a terahertz frequency band of 0.3 to 3.0 THz, have been drawing attention as elemental technology for high-speed wireless communication using millimeter waves, non-destructive internal inspection using 3D imaging, and component analysis using electromagnetic wave absorption. Generally, field-effect transistors composed of compound semiconductor materials with particularly high electron mobility in terms of physical properties are used as electronic devices with good high-frequency characteristics.

The field-effect transistor has a semiconductor substrate, a gate electrode formed on the surface of the semiconductor substrate, and a source electrode and a drain electrode that are formed on both sides of the gate electrode with ohmic connection. Especially, a high electron mobility transistor (HEMT) with excellent high-frequency characteristics has a configuration in which, for example, a buffer layer, a channel layer, a barrier layer and a cap layer are laminated on the semiconductor substrate in this order from the substrate side (NPL 1). Further, a carrier supply layer is formed on the barrier layer side with respect to the channel layer, or alternatively, the buffer layer side with respect to the channel layer. In such a configuration, a position and doping amount of the carrier supply layer are designed in response to an energy band design.

When applying a potential to the gate electrode, carriers are supplied from the carrier supply layer to the channel layer in accordance with the intensity of the applied potential, therefore a concentration of a two-dimensional electron gas is modulated, whereby electrons move through a conduction channel formed between the source electrode and the drain electrode. In the HEMT structure, a channel layer through which carriers travel and an electron supply layer are spatially separated to suppress scattering due to impurity. With this configuration, electron mobility can be improved, and thus terahertz operation can be realized.

In order to apply a HEMT to a terahertz integrated circuit, it is important to improve the high-frequency characteristics. For this purpose, it is one method to minimize as much as possible the parasitic capacitance between the gate electrode and the source electrode/drain electrode. As a fundamental method for reducing the parasitic capacitance, it is conceivable that a gate electrode forming surface and source electrode and drain electrode forming surfaces are formed separately from each other vertically with reference to a channel surface.

Focusing on the field-effect transistor structure, for example, in NPL 2, as shown in FIG. 3(b) of NPL 2, a thin film transistor (TFT) for a display using an organic EL adopts a structure in which a bottom gate electrode is embedded in a layer of SiO₂, and a channel composed of InGaZnO (IGZO) and source/drain regions are formed on the top of the bottom gate electrode. In this example, the excimer laser irradiation is performed from the bottom gate electrode to selectively reduce the sheet resistance of the source/drain regions, thereby reducing the on-resistance. Further, since the gate electrode and the source/drain regions can be formed in a self-alignment manner, an increase in unnecessary parasitic capacitance can be suppressed.

Also, in NPL 3, as shown in FIG. 1 of NPL 3, in the electro-physiological-chemical FET sensor array, a structure in which a via is formed for the well region in the source/drain regions of each FET so as to pass through the rear side, and the via and the source/drain regions are connected, is adopted. With this structure, the space of the front side sensor part can be made wide, and the sensing accuracy of the biological signal can be improved.

### CITATION LIST

### Non Patent Literature

NPL 1: T. Suemitsu et al., “Improved Recessed-Gate Structure for Sub-0.1-μm-Gate InP-Based High Electron Mobility Transistors”, Japanese Journal of Applied Physics, vol. 37, No. 1363-1372, 1998.
NPL 2: M. Nakata et al., “Fabrication method for self-aligned bottom-gate oxide thin-film transistors by utilizing backside excimer-laser irradiation through substrate”, Applied Physics Letters, vol. 103, 142111, 2013.
NPL 3: S. Ingebrandt et al., “Backside contacted field effect transistor array for extracellular signal recording”, Biosensors and Bioelectronics, vol. 18, pp. 429-435, 2003.

### SUMMARY

### Technical Problem

However, when the field-effect transistor in the techniques of NPLs 2 and 3 are applied to the HEMT structure, there are the following problems.

In NPL 2, a gate electrode composed of metal is disposed on the substrate side from the viewpoint of a channel composed of IGZO and embedded in SiO₂, and a channel region and source/drain regions are disposed on the top thereof using SiO₂ as a barrier layer. In the HEMT structure shown in NPL 1, since the source/drain electrodes and the gate electrode are disposed on the upper side of the channel from the viewpoint of the substrate, the configuration of NPL 2 cannot be applied just as it is. Further, in NPL 2, the gate electrode should be connected to the gate wiring disposed on the upper side of the channel via the through wiring penetrating the channel and the SiO₂ layer. Such routing of the wiring causes delay, parasitic capacitance, etc., and can cause a trouble in the operation of the terahertz frequency band as described above. In such a state, the high-frequency characteristics cannot be improved.

In NPL 3, the well region for forming the ohmic junction is formed by doping or diffusion, and the ohmic junction is formed from the rear side with respect to the well region. However, in order to sufficiently reduce the sheet resistance of the well region, it is necessary to carry out an annealing process for activating the dopant. For a HEMT, particularly in the case of a channel using InP, GaAs or the like, if a high-temperature annealing treatment such as an FET using Si is performed due to a problem of thermal stability, there is a possibility that the performance of the transistor is deteriorated by reduction of impurity concentration due to diffusion of the impurity in the carrier supply layer or diffusion of the gate electrode material or the like.

Embodiments of the present invention can solve the problems stated above and an object of the present invention is to realize a further speedup of the high electron mobility transistor without causing deterioration in characteristics of the transistor.

### Solution to Problem

A semiconductor device according to embodiments of the present invention is includes a field-effect transistor having: a first barrier layer including a compound semiconductor; a channel layer including a compound semiconductor that is formed on the first barrier layer; a second barrier layer including a compound semiconductor that is formed on the channel layer; a gate electrode formed on the second barrier layer; a source electrode and a drain electrode formed with the gate electrode interposed therebetween; a first carrier supply layer formed on the first barrier layer side of the channel layer; a second carrier supply layer formed between the gate electrode and the channel layer; and a groove penetrating the first barrier layer in a region where the gate electrode is formed, in which at least one of the source electrode and the drain electrode is formed on the first barrier layer side of the channel layer.

### Advantageous Effects of Embodiments of the Invention

As described above, according to embodiments of the present invention, since the gate electrode is disposed on the second barrier layer disposed on the channel layer, and at least one of the source electrode and the drain electrode is disposed on the lower side of the first barrier layer disposed under the channel layer, the high electron mobility transistor can be further increased in speed without causing deterioration in characteristics of the transistor.

### BRIEF DESCRIPTION OF THE DRAWINGS

FIG. 1 is a cross-sectional view showing a configuration of a semiconductor device according to an embodiment 1 of the present invention.

FIG. 2 is a cross-sectional view showing a configuration of a semiconductor device according to an embodiment 2 of the present invention.

FIG. 3 is a cross-sectional view showing a configuration of a semiconductor device according to an embodiment 3 of the present invention.

FIG. 4 is a cross-sectional view showing a configuration of a semiconductor device according to an embodiment 4 of the present invention.

### DETAILED DESCRIPTION OF ILLUSTRATIVE EMBODIMENTS

The semiconductor device according to the embodiments of the present invention will be described hereinafter.

### Embodiment 1

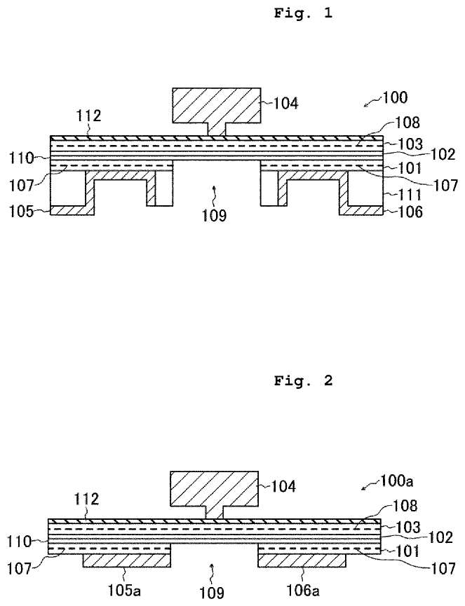

First, a semiconductor device according to an embodiment 1 of the present invention will be described with reference to FIG. 1. This semiconductor device is a field-effect transistor 100 including: a first barrier layer 101 including a compound semiconductor; a channel layer 102 including a compound semiconductor that is formed on the first barrier layer 101; a second barrier layer 103 including a compound semiconductor that is formed on the channel layer 102; a gate electrode 104 formed on the second barrier layer 103; a source electrode 105 and a drain electrode 106 formed with the gate electrode 104 interposed therebetween. The field-effect transistor 100 is a so-called high electron mobility transistor (HEMT).

Here, the field-effect transistor 100 includes a first carrier supply layer 107 formed on the first barrier layer 101 side of the channel layer 102, and a second carrier supply layer 108 formed between the gate electrode 104 and the channel layer 102. The first carrier supply layer 107 can be formed in the first barrier layer 101, and the second carrier supply layer 108 can be formed in the second barrier layer 103. Further, the field-effect transistor 100 includes a groove 109 penetrating the first barrier layer 101 formed extending in a gate width direction in a region where the gate electrode 104 is formed.

In the configuration of the semiconductor device according to the embodiment 1 described above, at least one of the source electrode 105 and the drain electrode 106 is formed at the first barrier layer 101 side (lower side) of the channel layer 102. Further, at least a part of one of the source electrode 105 and the drain electrode 106 is formed in contact with the first barrier layer 101. In this example, both of the source electrode 105 and the drain electrode 106 are formed at the first barrier layer side (lower side) of the channel layer 102. Further, both parts of the source electrode 105 and the drain electrode 106 are formed in contact with the first barrier layer 101. By the way, in the following description, the first barrier layer 101 side is referred to as a lower side and the second barrier layer 103 side is referred to as an upper side with reference to the channel layer 102.

Further, in this example, the first barrier layer 101, the channel layer 102, and the second barrier layer 103 are formed on a substrate 111 in this order. In this case, the groove 109 is formed penetrating the substrate 111 and the first barrier layer 101. Further, in this example, an etching stop layer 110 is provided. When the etching stop layer 110 is provided, a lower side of the etching stop layer 110 is exposed by the groove 109. Further, in this example, the gate electrode 104 is formed on (an upper side of) the second barrier layer 103 via a gate insulation layer 112.

For example, the substrate 111 can include of semi-insulating InP. The first barrier layer 101 can include, for example, InGaAs doped with Si at 1×10¹⁹ cm⁻³ to 2×10¹⁹ cm⁻³. Further, the first barrier layer 101 can be 5 to 20 nm in thickness. The first carrier supply layer 107 can be a doped layer (δ layer), in the first barrier layer 101, with Si at 1×10¹² cm⁻³ to 1×10¹³ cm⁻³ as an impurity by means of well-known sheet doping. By the way, generally, a buffer layer (not shown) including InAlAs having a thickness of 100 to 300 nm is formed on the substrate 111, and the first barrier layer 101 is formed on the buffer layer.

The etching stop layer 110 can include InP with a thickness of 2 to 5 nm. The channel layer 102 can include InGaAs with a thickness of 5 to 20 nm. Alternatively, the channel layer 102 can be a composite structure of an InGaAs layer and an InAs layer. The second barrier layer 103 can include InAlAs with a thickness of 5 to 20 nm. The second carrier supply layer 108 can be a doped layer (δ layer), in the second barrier layer 103, with Si at 1×10¹² cm⁻³ to 1×10¹³ cm⁻³ as an impurity by means of well-known sheet doping.

The layer of the compound semiconductor described above can be formed by crystal growth using a metal-organic chemical vapor deposition method, a molecular beam epitaxy method, or the like.

The gate insulation layer 112 can include an oxide or a nitride film such as SiO₂, SiN, Al₂O₃, HfO₂ or TiO₂ or a composite film of these. A thickness of the gate insulation layer 112 can fall within a range of approximately 1 to 10 nm, however, depending on the gate length.

The gate electrode 104 can be mainly formed by a composite structure of Ti, Pt, Au and Mo. In order to achieve a short gate length while reducing the gate resistance as much as possible, the gate electrode 104 can be T-shaped, Y-shaped, or T-shaped in which an upper portion has a wider area than a lower portion in a plan view. By the way, a gate insulation layer can also be formed on the etching stop layer.

The groove 109 can be formed by etching from the rear side of the substrate 111. For example, a mask pattern that includes openings at positions where the groove 109 should be formed is formed by using the well-known photolithography technique. Using the mask pattern as a mask, first, with the well-known etching process that is the predetermined etching process, the groove 109 is formed by removing the first barrier layer 101.

For example, first, the substrate 111 is etched to some extent by dry etching to make it thinner, and this thinned portion is selectively etched and removed by an etching process using a hydrochloric acid-based wet etchant. In this etching process, since the first barrier layer 101 including InGaAs is hardly etched, the first barrier layer 101 is made to function as an etching stop layer, and the thinned portion of the substrate 111 including InP can be selectively etched.

Next, the first barrier layer 101 is selectively etched and removed by using, for example, an etchant including phosphoric acid and a hydrogen peroxide solution or an etchant including citric acid and a hydrogen peroxide solution. In this etching process, the substrate 111 including InP and the etching stop layer 110 including InP are not etched. Therefore, the etching stop layer 110 is allowed to function as an etching stop layer, so that the first barrier layer 101 can be selectively etched.

The center position of the groove 109 in a plan view should be basically aligned with the center position of the gate electrode 104 formed on the upper side (surface side) of the channel layer 102. A length of the groove 109 in the gate length direction can be approximately 20 to 200 nm, however considering the difficulty in miniaturization for rear side processing, it can be set to approximately 10 to 20 μm. Alternatively, the groove 109 can be a state filled with an insulating compound semiconductor formed by crystal regrowth, an insulating resin, or the like.

The source electrode 105 and the drain electrode 106 can include, for example, a laminated structure of metal such as Ti, Pt, Au, or Ni. The source electrode 105 and the drain electrode 106 are formed with ohmic-connecting to the first barrier layer 101 within the through hole formed in the substrate 111. The source electrode 105 and the drain electrode 106 are formed in the through hole formed in the substrate of the corresponding position by conformally forming the electrode material or forming so as to fill the through hole.

According to the embodiment 1 described above, since the first barrier layer 101 to which the source electrode 105 and the drain electrode 106 are ohmic connected with low resistance is formed on the lower side of the channel layer 102, the gate electrode 104 can be disposed on the upper side of the channel layer 102, and the source electrode 105 and the drain electrode 106 can be disposed on the lower side of the channel layer 102. In this structure, since it is not necessary to form a well region requiring high temperature treatment, thermal characteristics deterioration causing a problem in a compound semiconductor is not caused, and ohmic junction with low resistance in the source electrode 105 and the drain electrode 106 can be realized. According to the embodiment 1, since the gate electrode 104 is disposed on the upper side of the channel layer 102, and the source electrode 105 and the drain electrode 106 are disposed on the lower side of the channel layer 102, with the structure in which the parasitic capacitance between the source electrode 105 and the drain electrode 106 is reduced, the high frequency characteristics can be further improved without causing deterioration in the characteristics of the transistor.

### Embodiment 2

The semiconductor device according to an embodiment 2 of the present invention will be described with reference to FIG. 2. This semiconductor device is a field-effect transistor 100a including a first barrier layer 101 including a compound semiconductor; a channel layer 102 including a compound semiconductor that is formed on the first barrier layer 101; a second barrier layer 103 including a compound semiconductor that is formed on the channel layer 102; a gate electrode 104 formed on the second barrier layer 103; and a source electrode 105a and a drain electrode 106a formed with the gate electrode 104 interposed therebetween.

Also in the embodiment 2, similarly to the embodiment 1, the field-effect transistor 100a includes a first carrier supply layer 107 formed on the first barrier layer 101 side of the channel layer 102, and a second carrier supply layer 108 formed between the gate electrode 104 and the channel layer 102. The first carrier supply layer 107 can be formed in the first barrier layer 101, and the second carrier supply layer 108 can be formed in the second barrier layer 103. Further, the field-effect transistor 100a has a groove 109 penetrating the first barrier layer 101 formed extending in the gate width direction in a region where the gate electrode 104 is formed.

Further, at least one of the source electrode 105a and the drain electrode 106a is formed on the first barrier layer 101 side (lower side) of the channel layer 102. Further, at least one of the source electrode 105a and the drain electrode 106a is formed in contact with the first barrier layer 101. In this example, both of the source electrode 105a and the drain electrode 106a are formed on the first barrier layer 101 side (lower side) of the channel layer 102. Further, both of the source electrode 105a and the drain electrode 106a are formed in contact with the first barrier layer 101. In the embodiment 2, unlike the embodiment 1, the substrate 111 is removed and a groove 109 is formed in the first barrier layer 101.

According to the embodiment 2, since no groove is formed in the substrate, it is possible to form a finer groove 109, and the transistor characteristics can be controlled more easily.

### Embodiment 3

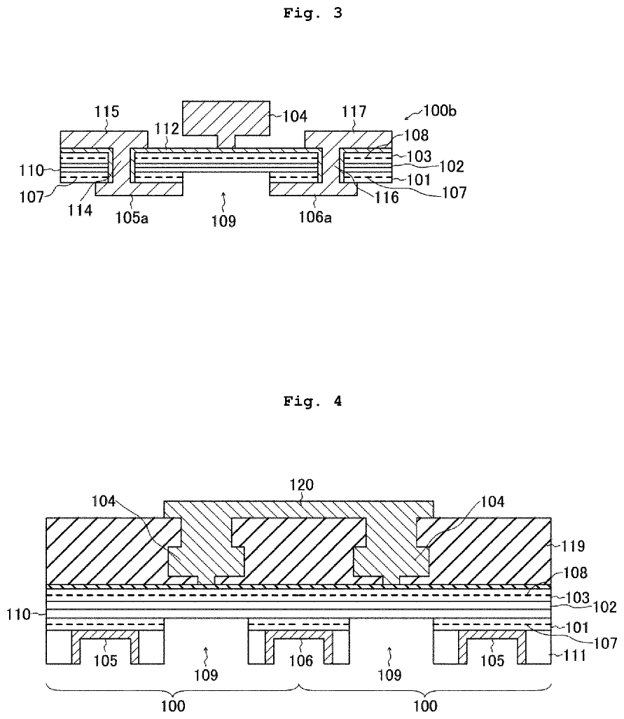

The semiconductor device according to an embodiment 3 of the present invention will be described with reference to FIG. 3. This semiconductor device is a field-effect transistor 100b including a first barrier layer 101 including a compound semiconductor; a channel layer 102 including a compound semiconductor that is formed on the first barrier layer 101; a second barrier layer 103 including a compound semiconductor that is formed on the channel layer 102; a gate electrode 104 formed on the second barrier layer 103; and a source electrode 105a and a drain electrode 106a formed with the gate electrode 104 interposed therebetween.

Also in the embodiment 3, similarly to the embodiment 2 described above, the field-effect transistor 100b includes a first carrier supply layer 107 formed on the first barrier layer 101 side of the channel layer 102, and a second carrier supply layer 108 formed between the gate electrode 104 and the channel layer 102. The first carrier supply layer 107 can be formed in the first barrier layer 101, and the second carrier supply layer 108 can be formed in the second barrier layer 103. Further, the field-effect transistor 100b has a groove 109 penetrating the first barrier layer 101 formed extending in the gate width direction in a region where the gate electrode 104 is formed.

Further, at least one of the source electrode 105a and the drain electrode 106a is formed on the first barrier layer 101 side (lower side) of the channel layer 102. Further, at least one of the source electrode 105a and the drain electrode 106a is formed in contact with the first barrier layer 101. In this example, both of the source electrode 105a and the drain electrode 106a are formed on the first barrier layer 101 side (lower side) of the channel layer 102. Further, both of the source electrode 105a and the drain electrode 106a are formed in contact with the first barrier layer 101. Also in the embodiment 3, similarly to the embodiment 2, the substrate 111 is removed and the groove 109 is formed in the first barrier layer 101.

Further, in the embodiment 3, a source electrode 105 a formed on the first barrier layer 101 side of the channel layer 102 is connected to a source wiring 115 formed on the upper side of the first barrier layer 101 via a through wiring 114 penetrating the first barrier layer 101, the channel layer 102, the second barrier layer 103, the first carrier supply layer 107, and the second carrier supply layer 108. Similarly, a drain electrode 106a formed on the first barrier layer 101 side of the channel layer 102 is connected to a drain wiring 117 formed on the upper side of the first barrier layer 101 via a through wiring 116 penetrating the first barrier layer 101, the channel layer 102, the second barrier layer 103, the first carrier supply layer 107, and the second carrier supply layer 108.

### Embodiment 4

Next, the semiconductor device according to an embodiment 4 of the present invention will be described with reference to FIG. 4. This semiconductor device includes two field-effect transistors 100 with commonality of a drain electrode 106 therebetween. An interlayer insulation layer 119 is formed on the two field-effect transistors 100, and a gate wiring 120 is formed on the interlayer insulation layer 119. The gate wiring 120 is connected to each gate electrode 104 of the two field-effect transistors 100 by through electrodes formed penetrating the interlayer insulation layer 119.

The interlayer insulation layer 119 can include of a thermosetting resin, a UV curing resin or the like, an oxide, or a nitride-based material (insulating material) such as SiON or SiO₂. Further, the interlayer insulation layer 119 can typically have a thickness of several um to several hundred nm. Further, a source wiring is connected to the source electrode 105, and a drain wiring is connected to the drain electrode 106 on the lower side of the channel layer 102 (the rear side of the substrate 111). These wirings can include a metal such as Au, Cu, or Ti.

According to the embodiment 4, in the integrated circuit in which a plurality of field-effect transistors 100 are integrated, the source wiring and the drain wiring can be disposed on the rear side, so that the connection and the connecting distance between the gate electrodes 104 of the adjacent field-effect transistors 100 have the increased degree of freedom in layout, and electric resistance and parasitic capacitance can be further reduced.

Further, if the source wiring and the drain wiring are appropriately laid out, the degree of freedom in circuit design can be greatly improved. For example, in a case of a common-source, the source wiring is connected to the ground on the rear side just as it is, so that more stable grounding can be realized than grounding on the front side. Further, also in a drain feeder circuit, since the bias can be managed using the wide size of the drain wiring disposed on the rear side, not only with increasing the degree of the freedom in layout of the front side, but also with applying the thicker wiring of the rear side, the wiring with higher current capacity can be formed.

As described above, according to embodiments of the present invention, since the gate electrode is disposed on the second barrier layer disposed on the channel layer, and at least one of the source electrode and the drain electrode is disposed on the lower side of the first barrier layer disposed under the channel layer, the high electron mobility transistor can be further increased in speed without causing deterioration in characteristics of the transistor. According to embodiments of the present invention, a source electrode and a drain electrode serving as ohmic electrodes are formed on the rear side without providing a well region as disclosed in NPL 3, thereby reducing parasitic capacitance generated between the gate electrode and the source electrode formed on the front side, so that the high frequency characteristics can be improved.

Note that it is clear that the present invention is not limited to the embodiments described above and, within the technical concept of the present invention, many modifications and combinations can be implemented by those skilled in the art.

1.-6. (canceled)

7. A semiconductor device comprising:
a field-effect transistor comprising:
a first barrier layer comprising a first compound semiconductor;
a channel layer comprising a second compound semiconductor disposed on an upper surface of the first barrier layer;
a second barrier layer comprising a third compound semiconductor disposed on an upper surface of the channel layer;
a gate electrode disposed above an upper surface the second barrier layer;
a source electrode and a drain electrode disposed with the gate electrode disposed therebetween, wherein the source electrode or the drain electrode is disposed below a lower surface of the first barrier layer;
a first carrier supply layer disposed below the lower surface of the first barrier layer;
a second carrier supply layer disposed on the upper surface of the second barrier layer between the gate electrode and the channel layer; and
a groove penetrating the first barrier layer in a region where the gate electrode is disposed.

8. The semiconductor device according to claim 7, further comprising a second field-effect transistor having a same structure as the field-effect transistor, wherein the field-effect transistor and the second field-effect transistor have commonality of the drain electrode therebetween.

9. The semiconductor device according to claim 7, wherein the source electrode or the drain electrode is in contact with the first barrier layer.

10. The semiconductor device according to claim 7, wherein the source electrode or the drain electrode that is disposed below the lower surface of the first barrier layer is connected to a source wiring or a drain wiring disposed on an upper side of the first barrier layer via a through wiring penetrating the first barrier layer, the channel layer, the second barrier layer, the first carrier supply layer, and the second carrier supply layer.

11. The semiconductor device according to claim 10, wherein the first carrier supply layer is disposed in the first barrier layer and the second carrier supply layer is disposed in the second barrier layer.

12. The semiconductor device according to claim 10, wherein the first barrier layer, the channel layer, and the second barrier layer are disposed on a substrate in this order.

13. The semiconductor device according to claim 7, wherein the first carrier supply layer is disposed in the first barrier layer and the second carrier supply layer is disposed in the second barrier layer.

14. The semiconductor device according to claim 7, wherein the first barrier layer, the channel layer, and the second barrier layer are disposed on a substrate in this order.

15. A method of manufacturing a semiconductor device comprising a field-effect transistor, the method comprising:
forming a channel layer comprising a first compound semiconductor;
forming a first barrier layer comprising a second compound semiconductor on a lower surface of the channel layer;
forming a second barrier layer comprising a third compound semiconductor on an upper surface of the channel layer;
forming a gate electrode above the upper surface of the channel layer;
forming a source electrode and a drain electrode with the gate electrode disposed therebetween, wherein the source electrode or the drain electrode is formed below the lower surface of the channel layer;
forming a first carrier supply layer below the lower surface of the channel layer;
forming a second carrier supply layer above the upper surface of the channel layer between the gate electrode and the channel layer; and
forming a groove penetrating the first barrier layer in a region underlying the gate electrode.

16. The method according to claim 15, wherein the source electrode or the drain electrode is in contact with the first barrier layer.

17. The method according to claim 15, wherein the source electrode or the drain electrode below the lower surface of the channel layer is connected to a source wiring or a drain wiring disposed on an upper side of the first barrier layer via a through wiring penetrating the first barrier layer, the channel layer, the second barrier layer, the first carrier supply layer, and the second carrier supply layer.

18. The method according to claim 17, further comprising forming the first carrier supply layer in the first barrier layer and forming the second carrier supply layer in the second barrier layer.

19. The method according to claim 17, wherein the first barrier layer, the channel layer, and the second barrier layer are formed on a substrate in this order.

20. The method according to claim 15, further comprising forming the first carrier supply layer in the first barrier layer and forming the second carrier supply layer in the second barrier layer.

21. The method according to claim 15, wherein the first barrier layer, the channel layer, and the second barrier layer are formed on a substrate in this order.

22. The method according to claim 15, wherein the source electrode and the drain electrode are formed below the lower surface of the channel layer.
